(19) United States
(12) Patent Application Publication
(10) Pub. No.: US 2025/0140573 A1
(43) Pub. Date: May 1, 2025

(54) METHOD OF MANUFACTURING PRE-MOLDED LEAD FRAME FOR PACKAGING

(71) Applicant: PANJIT INTERNATIONAL INC., Kaohsiung City (TW)

(72) Inventors: Chung Hsiung HO, Kaohsiung City (TW); Wei-Ming HUNG, Kaohsiung City (TW); Shun Chi SHEN, Kaohsiung City (TW)

(73) Assignee: PANJIT INTERNATIONAL INC., Kaohsiung City (TW)

(21) Appl. No.: 18/399,678

(22) Filed: Dec. 28, 2023

(30) Foreign Application Priority Data
Oct. 30, 2023 (TW) 112141469

(51) Int. Cl. H01L 21/48; H01L 21/56; H01L 21/683

(52) U.S. Cl. CPC H01L 21/4821; H01L 21/565; H01L 21/6835; H01L 2221/68372

(57) ABSTRACT

A method of manufacturing pre-molded lead frame for packaging is disclosed. A first patterned aluminum metal layer is formed on a temporary carrier. A displacement reaction procedure is performed, in which at least part of the first patterned aluminum metal layer is replaced by copper metal so as to form a first copper metal wiring layer. A first molding compound is formed around the first copper metal wiring layer. The temporary carrier is removed.

This application claims priority under 35 U.S.C. § 119(a) on Patent Application No(s). 112141469 filed in Taiwan, R.O.C. on Oct. 30, 2023, the entire contents of which are hereby incorporated by reference.

### BACKGROUND

### 1. Technical Field

The present disclosure relates to a method of manufacturing lead frame, more particularly to a pre-molded lead frame for semiconductor packaging.

### 2. Related Art

As an essential element within a semiconductor packaging structure, a lead frame is provided for electrical connection between a chip and an external circuity. With the development of technology, a pre-molded lead frame for semiconductor packaging have gradually become a mainstream in order to reduce the dimensions of packaging structure and manufacturing costs.

### SUMMARY

According to one aspect of the present disclosure, a method of manufacturing pre-molded lead frame for packaging is disclosed. A first patterned aluminum metal layer is formed on a temporary carrier. A displacement reaction procedure is performed, in which at least part of the first patterned aluminum metal layer is replaced by copper metal so as to form a first copper metal wiring layer. A first molding compound is formed around the first copper metal wiring layer. The temporary carrier is removed.

### BRIEF DESCRIPTION OF THE DRAWINGS

FIG. 1 through FIG. 7 are schematic views of manufacturing a pre-molded lead frame for packaging according to one embodiment of the present disclosure;

FIG. 8 is a schematic view of a configuration of copper metal wiring layer according to another embodiment of the present disclosure;

FIG. 9 is a schematic view of a semiconductor packaging structure including pre-molded lead frame according to one embodiment of the present disclosure; and

FIG. 10 is a schematic view of a semiconductor packaging structure including pre-molded lead frame according to another embodiment of the present disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present disclosure. The following embodiments further illustrate various aspects of the present disclosure, but are not meant to limit the scope of the present disclosure.

In one aspect, generally, a pre-molded lead frame is manufactured by bending or etching a metal sheet into a desired shape, and this shaped metal sheet is then encapsulated by molding compound. However, since various products may have different distributions of electrical interconnections on chips or that of solder joints on circuit boards, manufacturers may need to prepare multiple molds to fabricate the lead frames that meet product specifications, Consequently, reducing manufacturing costs for lead frames becomes challenging.

One aspect of the present disclosure provides a pre-molded lead frame for packaging to improve or solve the one or more aforementioned problems.

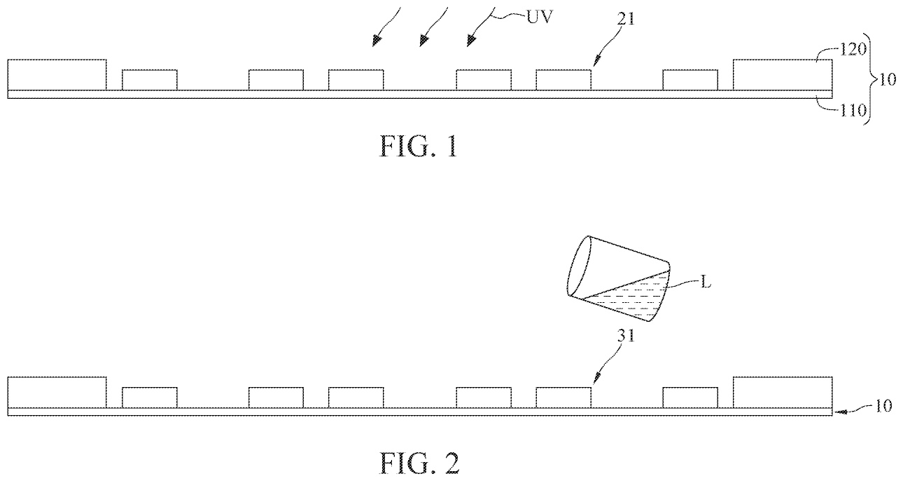

Please refer to FIG. 1 through FIG. 7 which show schematic views of manufacturing a pre-molded lead frame for packaging according to one embodiment of the present disclosure. As shown in FIG. 1, a temporary carrier 10 is provided. The temporary carrier 10 may include a substrate 110 and an outer frame 120 configured to secure the substrate 110. The substrate 110 is, for example but not limited to, a thermal release tape or an acid-resistant protective film.

Next, a patterned aluminum metal layer 21 is formed on the temporary carrier 10.

In this embodiment, the patterned aluminum metal layer 21 may be formed by screen printing. Specifically, the patterned aluminum metal layer 21 may be made of an aluminum paste containing aluminum powder and curable paste. The aluminum paste is printed on the temporary carrier 10 by screen printing in a pattern that matches the distribution of electrical interconnections on a chip or the distribution of soldering points on a circuit board. The curable paste is solidified to form the patterned aluminum metal layer 21.

In this embodiment, the aluminum powder in the patterned aluminum metal layer 21 may consist of pure aluminum powder, aluminum alloy powder or copper-clad aluminum powder, in which the proportion of aluminum in the aluminum powder may be greater than or equal to 60%. The curable paste may include optically curable paste or thermally curable paste. The patterned aluminum metal layer 21 may be formed by light curing or thermal curing. FIG. 1 exemplarily depicts the formation of the patterned aluminum metal layer 21, which is performed by UV light curing to solidify the aluminum paste.

Referring to FIG. 1 and FIG. 2, a displacement reaction procedure is performed, such that at least part of the patterned aluminum metal layer 21 is replaced by copper metal to thereby form a copper metal wiring layer 31. In this embodiment, the displacement reaction procedure is performed by treating the patterned aluminum metal layer 21 with a copper metal solution L. Specifically, the temporary carrier 10 and the patterned aluminum metal layer 21 may be immersed in the copper metal solution L or rinsed by the copper metal solution L.

In this embodiment, the copper metal solution L may be a copper sulfate solution. The patterned aluminum metal layer 21 undergoes a displacement reaction with copper sulfate, such that aluminum metal in the patterned aluminum metal layer 21 dissociates into the copper sulfate solution, and copper ions from the copper sulfate precipitate and grow on the outer surface of the patterned aluminum metal layer 21. The displacement reaction procedure in this embodiment is performed within appropriate reaction temperature and reaction time, causing aluminum metal to be replaced by copper metal, thereby replacing the patterned aluminum metal layer 21 in FIG. 1 with the copper metal wiring layer 31. The copper metal in the copper metal wiring layer 31 may consist of pure copper or copper aluminum alloy, in which the proportion of copper in the copper metal wiring layer 31 may be greater than or equal to 60%.

In FIG. 2, an entirety of the patterned aluminum metal layer 21 is replaced by copper metal so as to form the copper metal wiring layer 31 without aluminum metal therein, but the present disclosure is not limited thereto. FIG. 8 is a schematic view of a configuration of copper metal wiring layer according to another embodiment of the present disclosure. In FIG. 8, only part of the patterned aluminum metal layer near the outer surface thereof is replaced by copper metal so as to generate a copper metal wiring layer 31″ including an aluminum metal core 310 coated with a copper metal film 320. Herein, the term “without aluminum metal” refers to that the proportion of aluminum metal in the copper metal wiring layer may be less than or equal to 10%, preferably less than or equal to 1%.

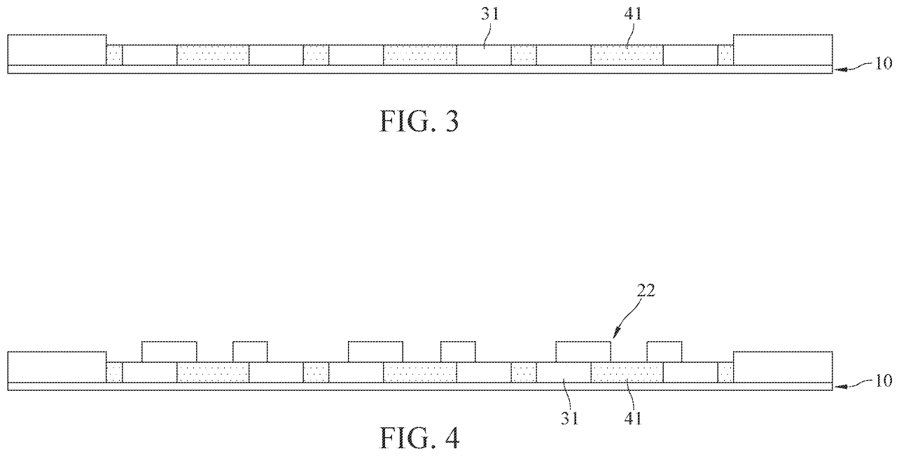

Referring to FIG. 3, a molding compound 41 is formed around the copper metal wiring layer 31. In this embodiment, the molding compound 41 is formed on the temporary carrier 10 to cover a lateral surface of the copper metal wiring layer 31 and expose a top surface of the copper metal wiring layer 31. The molding compound 41 may be made of organic composite material, resin composite material, macromolecule composite material, polymer composite material or other solid molding materials. For example, the molding compound 41 may be made of epoxy resin.

Referring to FIG. 4, a patterned aluminum metal layer 22 is formed on the copper metal wiring layer 31. In this embodiment, the patterned aluminum metal layer 22 may be formed by screen printing. Specifically, an aluminum paste may be printed on the copper metal wiring layer 31 as well as the molding compound 41 by screen printing. The aluminum paste is solidified to form the patterned aluminum metal layer 22. Any reference to the composition and properties of the aluminum paste and the patterned aluminum metal layer 22 can be found in the preceding description, and thus will be omitted hereafter.

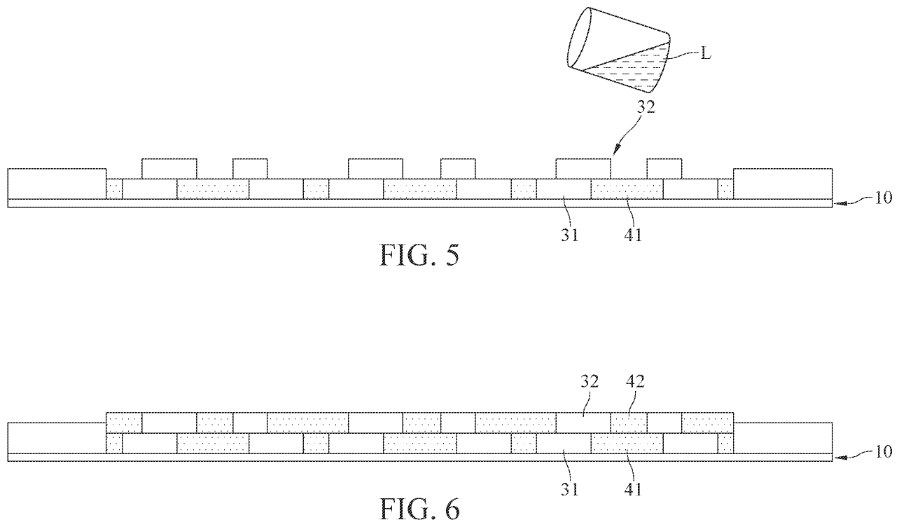

Referring to FIG. 4 and FIG. 5, another displacement reaction procedure is performed, such that at least part of the patterned aluminum metal layer 22 is replaced by copper metal to thereby form a copper metal wiring layer 32. In this embodiment, the displacement reaction procedure is performed by treating the patterned aluminum metal layer 22 with a copper metal solution L. The another displacement reaction procedure in this embodiment is performed within appropriate reaction temperature and reaction time, causing aluminum metal to be replaced by copper metal, thereby replacing the patterned aluminum metal layer 22 in FIG. 4 with the copper metal wiring layer 32. Any reference to the composition and properties of the copper metal wiring layer 32 can be found in the preceding description, and thus will be omitted hereafter.

Referring to FIG. 6, a molding compound 42 is formed around the copper metal wiring layer 32. In this embodiment, the molding compound 42 is formed on the molding compound 41 to cover a lateral surface of the copper metal wiring layer 32 and expose the top surface of the copper metal wiring layer 32. The molding compound 42 may be made of epoxy resin.

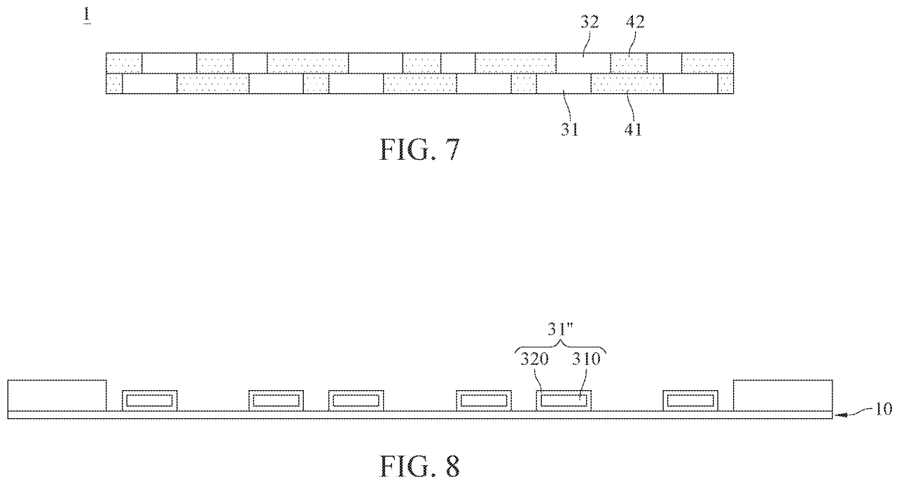

Referring to FIG. 7, the temporary carrier 10 is removed so as to obtain a pre-molded lead frame 1 including the copper metal wiring layers 31, 32 and the molding compounds 41, 42. The pre-molded lead frame 1 may include quad flat no-lead (QFN) package, but the present disclosure is not limited thereto.

In this embodiment, the pre-molded lead frame 1 includes a configuration of dual wiring layers (copper metal wiring layers 31, 32). However, the present disclosure is not limited thereto. In some other embodiments, the steps illustrated in FIG. 4 through FIG. 6 may be omitted, such that the pre-molded lead frame may include a configuration of single wiring layer. For example, the pre-molded lead frame may include only the copper metal wiring layer 31 without the copper metal wiring layer 32.

According to the disclosure, the displacement reaction refers to a reduction-oxidation reaction. The displacement reaction may more specifically refer to a galvanic displacement reaction.

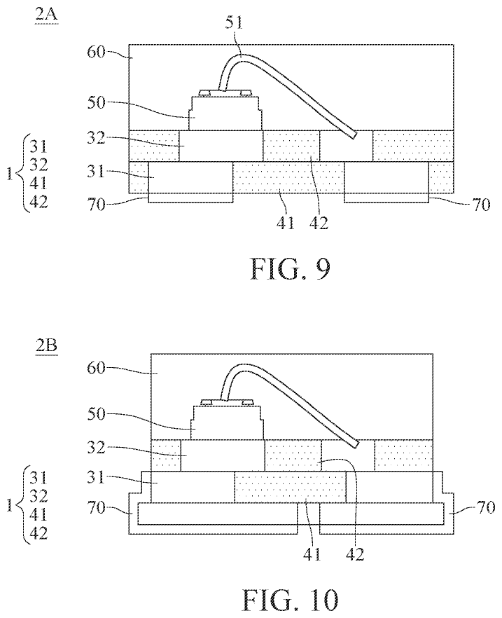

The pre-molded lead frame of the present disclosure may be applicable to semiconductor package. FIG. 9 is a schematic view of a semiconductor packaging structure including pre-molded lead frame according to one embodiment of the present disclosure. In this embodiment, a semiconductor packaging structure 2A may include a chip 50, an encapsulation 60 and the pre-molded lead frame 1 in FIG. 7. The chip 50 as well as a wire bonding 51 are provided at one side of the pre-molded lead frame 1, and the one side of the pre-molded lead frame 1 is covered by the encapsulation 60. An electroless nickel immersion gold (ENIG) layer 70 may be formed on a bottom surface of the copper metal wiring layer 31 by treatment at opposite side of the pre-molded lead frame 1.

FIG. 10 is a schematic view of a semiconductor packaging structure including pre-molded lead frame according to another embodiment of the present disclosure. In this embodiment, a semiconductor packaging structure 2B may include a chip 50, an encapsulation 60 and the pre-molded lead frame 1 in FIG. 7. The molding compounds 41, 42 of the pre-molded lead frame 1 are partially removed so as to expose the lateral surface of the copper metal wiring layer 31. An ENIG layer 70 may be formed on the lateral surface of the copper metal wiring layer 31 by treatment on the pre-molded lead frame 1.

According to the present disclosure, at least part of the patterned aluminum metal layer is replaced by copper metal, through displacement reaction, so as to form a copper metal wiring layer. A lead frame including a copper metal wiring layer with a suitable pattern for meeting product specification can be manufactured. In comparison to the conventional manufacturing methods that involve the use of mold to process a metal sheet, the method of the present disclosure forms one or more copper metal wiring layers by displacement reaction, which employs the advantage of lower manufacturing costs.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A method of manufacturing pre-molded lead frame for packaging, comprising:
forming a first patterned aluminum metal layer on a temporary carrier;
performing a displacement reaction procedure, wherein at least part of the first patterned aluminum metal layer is replaced by copper metal so as to form a first copper metal wiring layer;
forming a first molding compound around the first copper metal wiring layer; and
removing the temporary carrier.

2. The method of manufacturing pre-molded lead frame for packaging according to claim 1, wherein the first patterned aluminum metal layer is formed on the temporary carrier by screen printing with light curing or thermal curing.

3. The method of manufacturing pre-molded lead frame for packaging according to claim 2, wherein the first patterned aluminum metal layer comprises an aluminum powder and a curable paste.

4. The method of manufacturing pre-molded lead frame for packaging according to claim 1, wherein the displacement reaction procedure is performed by treating the first patterned aluminum metal layer with a copper metal solution.

5. The method of manufacturing pre-molded lead frame for packaging according to claim 1, wherein an outer surface of the first patterned aluminum metal layer is replaced by copper metal so as to form the first copper metal wiring layer comprising an aluminum metal core coated with a copper metal film.

6. The method of manufacturing pre-molded lead frame for packaging according to claim 1, wherein an entirety of the first patterned aluminum metal layer is replaced by copper metal so as to form the first copper metal wiring layer without aluminum metal therein.

7. The method of manufacturing pre-molded lead frame for packaging according to claim 1, further comprising:
forming a second patterned aluminum metal layer on the first copper metal wiring layer;
performing another displacement reaction procedure, wherein at least part of the second patterned aluminum metal layer is replaced by copper metal so as to form a second copper metal wiring layer; and
forming a second molding compound around the second copper metal wiring layer.

8. The method of manufacturing pre-molded lead frame for packaging according to claim 7, wherein the another displacement reaction procedure is performed by treating the second patterned aluminum metal layer with a copper metal solution.

9. The method of manufacturing pre-molded lead frame for packaging according to claim 7, wherein an outer surface of the second patterned aluminum metal layer is replaced by copper metal so as to form the second copper metal wiring layer comprising an aluminum metal core coated with a copper metal film.

10. The method of manufacturing pre-molded lead frame for packaging according to claim 7, wherein an entirety of the second patterned aluminum metal layer is replaced by copper metal so as to form the second copper metal wiring layer without aluminum metal therein.
